(19) United States
(12) Patent Application Publication
(10) Pub. No.: US 2016/0068961 A1
(43) Pub. Date: Mar. 10, 2016

(54) Method and Apparatus For Growing Binary, Ternary and Quaternary Materials on a Substrate

(71) Applicant: AIXTRON SE, Herzogenrath (DE)

(72) Inventors: Ming-Te Liu, Sunnyvale, CA (US); Lin Yang, Sunnyvale, CA (US); Jerry Mack, Sunnyvale, CA (US); Zia Karim, Sunnyvale, CA (US); Brian Lu, Sunnyvale, CA (US)

(21) Appl. No.: 14/478,919

(22) Filed: Sep. 5, 2014

(51) Int. Cl. C23C 16/52; C23C 16/455

(52) U.S. Cl. CPC C23C 16/52; C23C 16/45544; C23C 16/455

(57) ABSTRACT

Methods and systems for forming a material on a substrate are provided. Aspects of the methods involve the controlled introduction of a plurality of vapor reactants into a deposition chamber to form a material on the substrate having uniform surface roughness, conformality, thickness and composition. Aspects of the systems include a vapor feed component, a vapor distribution component, a containment component, and a controller configured to operate the systems to carry out the methods.

### INTRODUCTION

Complex, multi-element thin films find wide applications in advanced computing devices for memory and data storage. Two examples of such materials are magnetoresistive materials for STTRMA and chalcogenide glass materials for phase change memory applications. Phase change memory is one of the most promising solutions for next-generation non-volatile memory technology.

Phase change memory operation depends on the ability of a chalcogenide material to undergo structural transformations to change from amorphous to crystalline in a controlled and reversible manner. Chalcogenide glass materials that include GeSbTe compositions are typically produced using sputtering and/or physical vapor deposition (PVD) techniques. However, as device sizes continue to shrink, thin films that are grown using such techniques can no longer meet the required material properties for memory applications, such as uniform composition, surface roughness, process repeatability, and gapfill capabilities. The methods and systems disclosed herein address these and other needs.

### SUMMARY

Methods and systems for forming a material on a substrate are provided. Aspects of the methods involve the controlled introduction of a plurality of vapor reactants into a deposition chamber to form a material on the substrate having uniform surface roughness, conformality, thickness and composition. Aspects of the systems include a vapor feed component, a vapor distribution component, a containment component, and a controller configured to operate the systems to carry out the methods.

### BRIEF DESCRIPTION OF THE DRAWINGS

FIG. 1 shows example process sequences that can be performed using the subject systems and methods.

FIG. 2 shows an illustration of a system including a liquid handling component, a vapor feed component, a vapor distribution component, a containment component, and a substrate support component.

FIG. 3 shows an illustration of a system including a liquid handling component, a vapor feed component, a vapor distribution component, a containment component having walls that angle inward in the vertical direction, and a substrate support component.

FIG. 4 shows an illustration of a system including a liquid handling component, a vapor feed component, a vapor distribution component, a containment component having walls that angle outward in the vertical direction, and a substrate support component.

FIG. 5 shows an overhead illustration of a vapor distribution component having a circular shape, a containment component having a circular shape, and a substrate support component having a circular shape.

FIG. 6 shows an overhead illustration of a vapor distribution component having a circular shape, a containment component having a square shape, and a substrate support component having a circular shape.

FIG. 7 shows an overhead illustration of a vapor distribution component having a square shape, a containment component having a square shape, and a substrate support component having a square shape.

FIG. 8 shows an overhead illustration of a vapor distribution component having a square shape, a containment component having a circular shape, and a substrate support component having a square shape.

FIG. 9 shows a perspective illustration of a system, including a vapor distribution component, a containment component having vertical (non-angled) walls, and a substrate support component.

FIG. 10A shows surface roughness data collected from the center of a substrate, or wafer, prepared using the subject methods.

FIG. 10B shows surface roughness data collected from an edge position of a substrate, or wafer, prepared using the subject methods.

FIG. 11 shows switching speed data obtained from Sb rich GST materials and Te rich GST materials.

FIG. 12, Panels a-b show magnified images of a thin film of material created using the subject methods.

FIG. 13 shows a scanning electron microscope image of a thin film of material created using the subject methods. The inset graph shows the atomic percentage of Sb, Te and Ge at each of the indicated positions.

### DETAILED DESCRIPTION

Methods and systems for forming a material on a substrate are provided. Aspects of the methods involve the controlled introduction of a plurality of vapor reactants into a deposition chamber to form a material on the substrate having uniform surface roughness, conformality, thickness and composition. Aspects of the systems include a vapor feed component, a vapor distribution component, a containment component, and a controller configured to operate the systems to carry out the methods.

Before the present invention is described in greater detail, it is to be understood that this invention is not limited to particular embodiments described, as such may, of course, vary. It is also to be understood that the terminology used herein is for the purpose of describing particular embodiments only, and is not intended to be limiting, since the scope of the present invention will be limited only by the appended claims.

Where a range of values is provided, it is understood that each intervening value, to the tenth of the unit of the lower limit unless the context clearly dictates otherwise, between the upper and lower limit of that range and any other stated or intervening value in that stated range, is encompassed within the invention. The upper and lower limits of these smaller ranges may independently be included in the smaller ranges and are also encompassed within the invention, subject to any specifically excluded limit in the stated range. Where the stated range includes one or both of the limits, ranges excluding either or both of those included limits are also included in the invention.

Certain ranges are presented herein with numerical values being preceded by the term “about.” The term “about” is used herein to provide literal support for the exact number that it precedes, as well as a number that is near to or approximately the number that the term precedes. In determining whether a number is near to or approximately a specifically recited number, the near or approximating unrecited number may be a number which, in the context in which it is presented, provides the substantial equivalent of the specifically recited number.

Unless defined otherwise, all technical and scientific terms used herein have the same meaning as commonly understood by one of ordinary skill in the art to which this invention belongs. Although any methods and materials similar or equivalent to those described herein can also be used in the practice or testing of the present invention, representative illustrative methods and materials are now described.

All publications and patents cited in this specification are herein incorporated by reference as if each individual publication or patent were specifically and individually indicated to be incorporated by reference and are incorporated herein by reference to disclose and describe the methods and/or materials in connection with which the publications are cited. The citation of any publication is for its disclosure prior to the filing date and should not be construed as an admission that the present invention is not entitled to antedate such publication by virtue of prior invention. Further, the dates of publication provided may be different from the actual publication dates which may need to be independently confirmed.

It is noted that, as used herein and in the appended claims, the singular forms “a”, “an”, and “the” include plural referents unless the context clearly dictates otherwise. It is further noted that the claims may be drafted to exclude any optional element. As such, this statement is intended to serve as antecedent basis for use of such exclusive terminology as “solely,” “only” and the like in connection with the recitation of claim elements, or use of a “negative” limitation.

As will be apparent to those of skill in the art upon reading this disclosure, each of the individual embodiments described and illustrated herein has discrete components and features which may be readily separated from or combined with the features of any of the other several embodiments without departing from the scope or spirit of the present invention. Any recited method can be carried out in the order of events recited or in any other order which is logically possible.

### Methods

Methods in accordance with embodiments of the invention may be used to form a material on a substrate using atomic layer deposition (ALD)—and/or chemical vapor deposition (CVD)—like deposition processes and sequences. The subject methods provide for controlled introduction of a plurality of vapor reactants into a reaction chamber to form a material on a substrate. When executed using the subject systems, the methods as described herein result in the formation of a thin film on a substrate, wherein the thin film has advantageous features, such as uniform surface roughness, conformality, thickness and/or composition across the substrate (e.g., at a central position on the substrate as well as at an edge position on the substrate).

In some embodiments, the subject methods are used to produce a thin film on a substrate, wherein the thin film has a uniform surface roughness across the substrate. By “surface roughness” is meant a quantification of the vertical deviations of the surface from its ideal form. One measurement of surface roughness, referred to herein as “Ra,” may be calculated as an arithmetic average of absolute values collected over a defined area of a surface. In some embodiments, a thin film produced according to the subject methods has a surface roughness value Ra that is calculated at a central portion of the substrate that is at least about 90%, such as 95%, such as 96%, such as 97%, such as 98%, such as 99%, such as 99.5%, such as 99.9%, such as 100% identical to the surface roughness value Ra that is calculated at an edge portion of the substrate. By “central portion” of the substrate is meant a portion of the substrate that is located within a 10 mm radius around the center of the substrate. By “edge portion” of the substrate is meant a portion of the substrate that is located less than 10 mm away from an outer edge of the substrate.

In some embodiments, the subject methods are used to produce a thin film on a substrate, wherein the thin film has a uniform conformality across the substrate. The terms “conformality” or “conformal” as used herein mean a thin film that has a uniform thickness over morphologically uneven interfaces. In some embodiments, a thin film produced according to the subject methods has a conformality value at a central portion of the substrate that is at least about 90%, such as 95%, such as 96%, such as 97%, such as 98%, such as 99%, such as 99.5%, such as 99.9%, such as 100% identical to the conformality value at an edge portion of the substrate. By “central portion” of the substrate is meant a portion of the substrate that is located within a 10 mm radius around the center of the substrate. By “edge portion” of the substrate is meant a portion of the substrate that is located less than 10 mm away from an outer edge of the substrate.

In some embodiments, the subject methods are used to produce a thin film on a substrate, wherein the thin film has a uniform thickness across the substrate. By “thickness” is meant the distance between the lower surface of the thin film and the upper surface of the thin film. In some embodiments, a thin film produced according to the subject methods has a thickness at a central portion of the substrate that is at least about 90%, such as 95%, such as 96%, such as 97%, such as 98%, such as 99%, such as 99.5%, such as 99.9%, such as 100% identical to the thickness at an edge portion of the substrate. By “central portion” of the substrate is meant a portion of the substrate that is located within a 10 mm radius around the center of the substrate. By “edge portion” of the substrate is meant a portion of the substrate that is located less than 10 mm away from an outer edge of the substrate.

In some embodiments, the subject methods are used to produce a thin film on a substrate, wherein the thin film has a uniform composition across the substrate. By “composition” is meant the atomic percentage of each of the components in the film. In some embodiments, a thin film produced according to the subject methods has a composition at a central portion of the substrate that is at least about 90%, such as 95%, such as 96%, such as 97%, such as 98%, such as 99%, such as 99.5%, such as 99.9%, such as 100% identical to the thickness at an edge portion of the substrate. By “central portion” of the substrate is meant a portion of the substrate that is located within a 10 mm radius around the center of the substrate. By “edge portion” of the substrate is meant a portion of the substrate that is located less than 10 mm away from an outer edge of the substrate.

In some embodiments, a thin film produced according to the subject methods has a uniform composition over a morphologically distinct surface feature of a substrate. For example, in some embodiments, a film that is deposited over a surface feature of the substrate, such as a trench on the substrate, has a uniform composition at a plurality of locations along the surface feature. In some embodiments, a thin film produced according to the subject methods has a composition that is at least about 90%, such as 95%, such as 96%, such as 97%, such as 98%, such as 99%, such as 99.5%, such as 99.9%, such as 100% identical at each of a plurality of locations along a surface feature.

Aspects of the methods involve placing a substrate on a substrate support component, and positioning the substrate support component inside a containment component, as described further below. As used herein, the term “substrate” is to be understood as including silicon-on-insulator (SOI) or silicon-on-sapphire (SOS) technology, doped and undoped semiconductors, epitaxial layers of silicon supported by a base semiconductor foundation, and other semiconductor structures. Furthermore, when reference is made to a “substrate” in the following description, previous process steps may have been utilized to form regions or junctions in the base semiconductor structure or foundation. Once the substrate is in position inside the containment component, aspects of the methods involve introducing a first vapor reactant into a pre-reaction space above the substrate by passing the first vapor reactant through a vapor distribution component, also described further below. Once the first vapor reactant is introduced into the pre-reaction space, it is maintained in the pre-reaction space under a first set of conditions to contact and react with the substrate.

Reaction conditions in accordance with embodiments of the methods include controlled partial pressures of each vapor reactant. In some embodiments, a vapor reactant is introduced into the reaction chamber and is established at a partial pressure ranging from 0.001 to 4 Torr, such as 0.01, 0.05, 0.1, 0.5, 1.0, 1.5, 2.0, 2.5 or 3 Torr. In some embodiments, a vapor reactant is maintained in the reaction chamber at a temperature ranging from 50 to 700° C., such as 75, 100, 150, 200, 250, 300, 350, 400, 450, 500, 550, 600 or 650° C.

Aspects of the methods further involve introducing a second vapor reactant into the pre-reaction space by passing the second vapor reactant through the vapor distribution system, and modulating the pressure level within the pre-reaction space so that the second vapor reactant is established in the pre-reaction space at a target partial pressure in less than 1 second. Once the second vapor reactant is established at the target partial pressure within the pre-reaction space, it is maintained in the pre-reaction space under a second set of conditions to contact and react with the substrate. Methods in accordance with embodiments of the invention result in the production of a material (e.g., a thin film) on the substrate that has a uniform surface roughness, conformality, thickness and/or composition between a center position on the substrate and an edge position on the substrate.

In some embodiments, the methods further involve introducing a third vapor reactant into the pre-reaction space by passing the third reactant through the vapor distribution system, and modulating the pressure level within the pre-reaction space so that the third vapor reactant is established in the pre-reaction space at a target partial pressure in less than 1 second. Once the third vapor reactant is established at the target partial pressure within the pre-reaction space, it is maintained in the pre-reaction space under a third set of conditions to contact and react with the substrate.

In some embodiments, the methods further involve introducing a fourth vapor reactant into the pre-reaction space by passing the fourth reactant through the vapor distribution system, and modulating the pressure level within the pre-reaction space so that the fourth vapor reactant is established in the pre-reaction space at a target partial pressure in less than 1 second. Once the fourth vapor reactant is established at the target partial pressure within the pre-reaction space, it is maintained in the pre-reaction space under a fourth set of conditions to contact and react with the substrate.

In some embodiments, a vapor reactant comprises one single component, while in some embodiments, a vapor reactant comprises a mixture of two or more components, and aspects of the methods involve mixing or combining the two or more components of the vapor reactant in different locations with respect to a vapor distribution component, as described further below. In some embodiments, two or more components of a vapor reactant are mixed together before the vapor reactant is introduced into the vapor distribution component. In some embodiments, two or more components of a vapor reactant are mixed together within the vapor distribution component before passing into the pre-reaction space. In such embodiments, the two or more components of the vapor reactant can be mixed in a chamber within the vapor distribution component. In some embodiments, the two or more components of the vapor reactant are mixed together after the two or more components have passed through the vapor distribution component. In such embodiments, the two or more components of the vapor reactant are kept separate while passing through the vapor distribution component, and are mixed together in the pre-reaction space above the substrate.

In some embodiments, a vapor reactant comprises two or more components, such as three or more components, such as four components, any of which may be mixed together as described above, e.g., before entering the vapor distribution component, within the vapor distribution component (e.g., within a chamber in the vapor distribution component), or in the pre-reaction space (e.g., after passing through the vapor distribution component).

Aspects of the methods involve introducing the vapor reactants, as described above, into the pre-reaction space to contact and react with the substrate to form a material on the substrate. In some embodiments, the methods involve introducing one or more vapor reactants, such as two or more vapor reactants, such as three or more vapor reactants, such as four vapor reactants, as described above, into the pre-reaction space to contact and react with the substrate.

In some embodiments, a first vapor reactant is introduced into the pre-reaction space and is then completely removed from the pre-reaction space before a second vapor reactant is introduced into the pre-reaction space. In some embodiments, a first vapor reactant and a second vapor reactant are introduced into the pre-reaction space at the same time. In some embodiments, a first vapor reactant is introduced into the pre-reaction space at a first time, and a second vapor reactant is introduced into the pre-reaction space in a staggered manner, such that the first vapor reactant is introduced at a first time, and the second vapor reactant is introduced at a second, later time but before the first vapor reactant has been removed from the pre-reaction space. In such embodiments, a first vapor reactant and a second vapor reactant are both present in the pre-reaction space for an overlapping period of time, e.g., an overlapping residence time. In some embodiments, the time between the introduction of a first vapor reactant and the introduction of a second vapor reactant into the pre-reaction space ranges from 10 milliseconds (ms), up to 20 ms, up to 30 ms, up to 40 ms, up to 50 ms, up to 60 ms, up to 70 ms, up to 80 ms, up to 90 ms, up to 100 ms, up to 150 ms, up to 200 ms, up to 250 ms, up to 300 ms, up to 350 ms, up to 400 ms, up to 450 ms, up to 500 ms, up to 550 ms, up to 600 ms, up to 650 ms, up to 700 ms, up to 750 ms, up to 800 ms, up to 850 ms, up to 900 ms, up to 950 ms, or up to 1 second or more. In some embodiments, the overlapping period of time during which the first and second vapor reactants are both present in the pre-reaction space ranges from 100 ms, up to 200 ms, up to 300 ms, up to 400 ms, up to 500 ms, up to 600 ms, up to 700 ms, up to 800 ms, up to 900 ms, up to 1 second, up to 1.5 second, up to 2 second, up to 2.5 seconds, up to 3 second, up to 3.5 seconds, up to 4 second, up to 4.5 second, or up to 5 seconds or more.

Any suitable vapor reactant and/or liquid or vapor precursor thereof may be utilized in the subject methods and systems. In some embodiments, vapor reactants include, but are not limited to, Germanium (Ge, atomic number 32), Antimony (Sb, atomic number 51), Tellurium (Te, atomic number 52), Nitrogen (N, atomic number 7), Carbon (C, atomic number 6), Aluminum (Al, atomic number 13), Boron (B, atomic number 5), Silicon (Si, atomic number 14), Gallium (Ga, atomic number 31), Indium (In, atomic number 49), Arsenic (As, atomic number 33), Phosphorus (P, atomic number 15), Bismuth (Bi, atomic number 83) and Tin (Sn, atomic number 50).

In some embodiments, vapor reactants and/or liquid or vapor precursors thereof may be solid, liquid, or gaseous at room temperature and atmospheric pressure. If the precursors are in a solid or liquid form at room temperature and atmospheric pressure, the precursors may be vaporized before introduction into the reaction chamber. Vaporization of the precursors may be accomplished by conventional techniques, which are not described in detail herein. The precursors may be commercially available or may be synthesized using conventional techniques.

In some embodiments, the methods involve introducing a reactant gas into the pre-reaction space. In some embodiments, a reactant gas is introduced into the pre-reaction space before the introduction of one or more vapor reactants. In some embodiments, a reactant gas is constantly delivered to the pre-reaction space while a vapor reactant is introduced into the pre-reaction space. In some embodiments, a vapor reactant is removed from the pre-reaction space before a reactant gas is introduced into the pre-reaction space. Reactant gases include but are not limited to ammonia (NH₃), hydrogen gas (H₂), oxygen gas (O₂), water (H₂O) and ozone gas (O₃).

In some embodiments, the methods involve introducing a purge gas into the pre-reaction space. In some embodiments, a purge gas is introduced into the pre-reaction space after a vapor reactant has been introduced into the pre-reaction space to remove the vapor reactant from the pre-reaction space. Purge gases include but are not limited to inert gases such as nitrogen (N₂), argon (Ar), helium (He), neon (Ne), krypton (Kr), xenon (Xe), or other gases that, although not inert, behave as inert under the subject reaction conditions.

In some embodiments of the methods, modulating the pressure level within the pre-reaction space comprises modulating a flow rate of a purge gas that passes through a gas injection orifice located on the containment component, as described further below. Any suitable purge gas flow rate can be used to achieve desired results. In some embodiments, the flow rate of a purge gas through a gas injection orifice ranges from 10 to 10,000 standard cubic centimeters per minute (sccm), such as 100, 200, 300, 400, 500, 600, 700, 800 or 900 sccm.

In some embodiments, the methods involve directing a flow of purge gas from a gas injection orifice into a space between the inner wall of the containment component and the outer edge of the substrate support component to modulate the pressure level within the pre-reaction space. In certain embodiments, the methods involve adjusting a delivery angle of one or more of the gas injection orifices to adjust the angle at which the purge gas enters the space between the substrate support component and the containment component. In certain embodiments, a gas injection orifice is adjusted to provide a delivery angle ranging from 5 to 85 degrees, such as 30 to 60 degrees, such as 45 degrees, with respect to the plane of the substrate support component. In some embodiments, the delivery angle of a gas injection orifice is fixed (i.e., cannot be adjusted) and as such, the methods involve modulating a flow rate of a purge gas through the gas injection orifice, but do not involve adjusting the delivery angle of the gas injection orifice.

In some embodiments, modulating the pressure within the pre-reaction space involves moving the substrate support component in the vertical direction. In some embodiments, the methods involve raising the substrate support component to reduce the volume of the pre-reaction space above the substrate. In other embodiments, the methods involve lowering the substrate support component to increase the volume of the pre-reaction space above the substrate. In some embodiments, the methods involve a combination of raising and lowering the substrate support component to achieve a desired volume of the pre-reaction space for different portions of a deposition sequence. For example, in some embodiments, the methods involve raising the substrate support component to reduce the volume of the pre-reaction space above the substrate while a first vapor reactant is introduced into the pre-reaction space, and then lowering the substrate support component to increase the volume of the pre-reaction space above the substrate while a second vapor reactant is introduced into the system.

In some embodiments of the methods, the substrate support component is moved in the vertical direction before a vapor reactant is introduced into the pre-reaction space. In some embodiments of the methods, the substrate support component is moved in the vertical direction after a vapor reactant is introduced into the pre-reaction space. In certain embodiments of the methods, the substrate support component is moved in the vertical direction while a vapor reactant is being introduced into the pre-reaction space.

In some embodiments, the methods involve modulating the temperature of the substrate support component. In some embodiments, the temperature of the substrate support component is increased or decreased as needed to achieve desired reaction conditions. For example, the temperature of the substrate support component can be adjusted to a temperature ranging from 50 to 700° C., such as 100, 200, 300, 400 500 or 600° C.

In some embodiments, the methods involve rotating the substrate support component about a central axis. In some embodiments, the substrate support component is rotated about the central axis while a vapor reactant, reactant gas or purge gas is introduced into the pre-reaction space. Any suitable rotation rate may be utilized to achieve desired reaction conditions for the substrate. In some embodiments, the rotation rate ranges from 1 to 50 revolutions per minute (RPM), such as 10 to 20 RPM.

In some embodiments, the methods involve modulating the temperature of the vapor distribution component. In some embodiments, the temperature of the vapor distribution component is increased or decreased as needed to achieve desired reaction conditions. For example, the temperature of the vapor distribution component can be adjusted to a temperature ranging from 50 to 300° C., such as 100, 150, 200 or 250° C.

In some embodiments, the methods involve modulating the temperature of the containment component. In some embodiments, the temperature of the containment component is increased or decreased as needed to achieve desired reaction conditions. For example, the temperature of the containment component can be adjusted to a temperature ranging from 50 to 500° C., such as 100 to 400° C.

In some embodiments, the methods involve modulating the temperature of the pre-reaction space. In some embodiments, the temperature of the pre-reaction space is increased or decreased as needed to achieve desired reaction conditions. For example, the temperature of the pre-reaction space can be adjusted to a temperature ranging from 50 to 700° C., such as 100, 200, 300, 400, 500, or 600° C.

In some embodiments, the methods involve modulating the pressure level within the pre-reaction space. For example, in some embodiments, the methods involve reducing the pressure within the pre-reaction space to create a vacuum. In some embodiments, the methods involve increasing the pressure within the pre-reaction space to a target pressure level. In some embodiments, the methods involve modulating the pressure level within the pre-reaction space from 10⁻¹ Torr up to 10² Torr, such as 2, 3, 4, 5, 6, 7, 8, 9, 10, 15, 20, 25, 30, 35, 40, 45, 50, 55, 60, 65, 70, 75, 80, 85, 90 or 95 Torr.

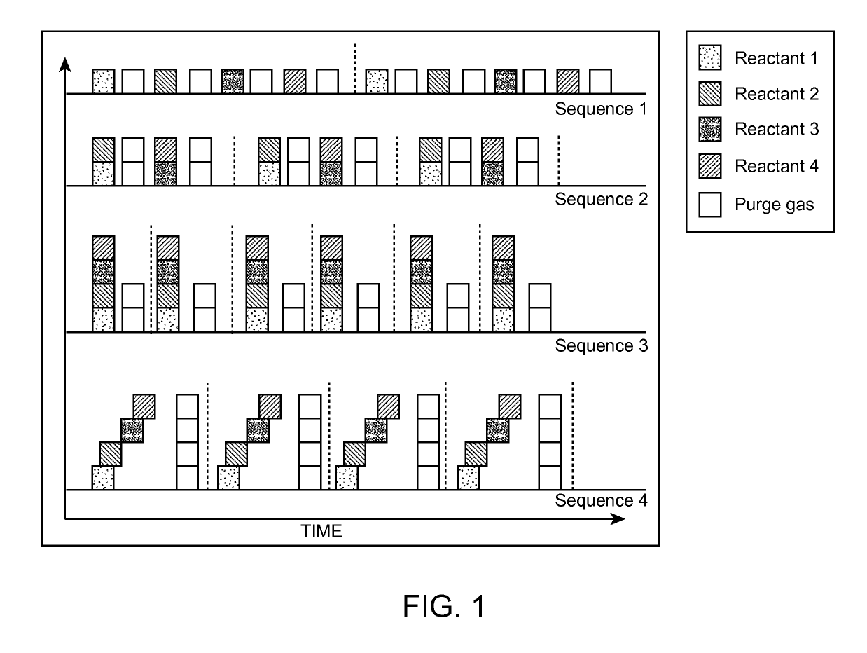

Referring now to FIG. 1, four different deposition sequences that can be carried out using the subject methods are depicted. The first deposition sequence, referred to as Sequence 1, shows an ALD sequence wherein a first vapor reactant is introduced into the reaction chamber to react with the substrate, and any unreacted portion of the first vapor reactant is removed from the chamber. Next, a second vapor reactant is introduced into the reaction chamber to react with the substrate, and any unreacted portion of the second vapor reactant is removed from the reaction chamber. Next, a third vapor reactant is introduced into the reaction chamber to react with the substrate, and any unreacted portion of the third vapor reactant is removed from the reaction chamber. Finally, a fourth vapor reactant is introduced into the reaction chamber to react with the substrate, and any unreacted portion of the fourth vapor reactant is removed from the reaction chamber. Following removal of the fourth vapor reactant from the reaction chamber, the process can be repeated by sequentially introducing each vapor reactant into the reaction chamber again. The result of this process is the sequential formation of a thin film of material on the substrate.

The second deposition sequence, referred to as Sequence 2, shows a CVD sequence wherein first and second vapor reactants are simultaneously introduced into the reaction chamber to react with the substrate. Following their reaction with the substrate, both the first and the second vapor reactants are removed from the reaction chamber. Next, a third and a fourth vapor reactant are simultaneously introduced into the reaction chamber to react with the substrate. Following their reaction with the substrate, the third and fourth vapor reactants are removed from the reaction chamber. Following removal of the third and fourth vapor reactants from the chamber, the process can be repeated by introducing the same vapor reactant pairs into the reaction chamber to react with the substrate in a sequential manner. The result of this process is the sequential formation of a thin film of material on the substrate.

The third deposition sequence, referred to as Sequence 3, depicts a process in which two vapor reactants are maintained in the reaction chamber at a constant level throughout the deposition process, and two other vapor reactants are introduced into the reaction chamber and removed from the reaction chamber at different stages of the deposition process. At the outset of Sequence 3, a first, second, third and fourth vapor reactant are simultaneously introduced into the reaction chamber to react with the substrate. After a designated period of time, the first and second vapor reactants are purged from the reaction chamber, while the third and fourth vapor reactants are maintained at a constant level within the reaction chamber to continue reacting with the substrate. Next, any remaining amount of the third and fourth vapor reactants is removed from the reaction chamber, and the process is repeated by introducing the first, second, third and fourth vapor reactants into the reaction chamber. Following a designated period of time, the first and second vapor reactants are removed from the reaction chamber, while the third and fourth vapor reactants are maintained at a constant level within the reaction chamber to continue reacting with the substrate. The result of this process is the sequential formation of a thin film of material on the substrate.

The fourth deposition sequence depicts a hybrid ALD/CVD-type process wherein the timing of the introduction of each vapor reactant into the reaction chamber is tightly controlled such that each vapor reactant is present in the reaction chamber for a designated residence time. Following the staggered introduction of each vapor reactant into the reaction chamber, all of the vapor reactants are removed from the reaction chamber, and the process is repeated. This process results in the formation of a thin film of material on the substrate.

### Systems

Aspects of the invention include systems that are configured or adapted for practicing the methods, e.g., as described above. In some embodiments, a system comprises a vapor distribution component that is configured to receive one or more vapor inputs and introduce the vapor inputs in the form of a vapor reactant into the pre-reaction space. In some embodiments, the vapor distribution component is configured to mix or combine two or more components of a vapor reactant before introducing the vapor reactant into the pre-reaction space.

In some embodiments, the vapor distribution component includes a plurality of chambers, such as one, two, three or four chambers. Chambers in accordance with embodiments of the vapor distribution component range in volume from 2.5 to 25 cubic inches, such as 10 to 15 cubic inches. Each chamber in the vapor distribution component is fluidly connected to each of a plurality of vapor inputs, as described further below. In some embodiments, the connection between a chamber and a vapor input comprises a valve, as also described further below. In some embodiments, each chamber of the vapor distribution component is fluidly connected to a plurality of nozzles that are configured to introduce a vapor reactant into the pre-reaction space. In some embodiments, a vapor distribution component includes a number of nozzles ranging from 10 to 1500, such as from 100 to 1200.

In some embodiments, a plurality of nozzles on the vapor distribution component is arranged in a distribution pattern. Distribution patterns in accordance with embodiments of the vapor distribution component include uniform and/or non-uniform spacing of the nozzles. In some embodiments, the nozzles are uniformly spaced in rows and columns to form a distribution pattern. In some embodiments, the nozzles are uniformly spaced in radially-oriented rows to form a distribution pattern. In some embodiments, certain nozzles may be clustered in one or more groups, while other nozzles may be uniformly distributed. Any suitable combination of nozzle spacing may be utilized to achieve a desired distribution pattern. In some embodiments, each of the plurality of chambers in the vapor distribution component is fluidly connected to a different set of nozzles, wherein each set of nozzles may be arranged in a specified distribution pattern.

Vapor distribution components in accordance with embodiments of the invention may have any suitable shape, such as square, rectangular, round, elliptical, or hexagonal when viewed from above. In some embodiments, the vapor distribution component comprises a faceplate that is removably coupled to the vapor distribution component. In such embodiments, the faceplate may have any suitable shape, such as square, rectangular, round, elliptical, or hexagonal, when viewed from above. In some embodiments, the faceplate may have the same shape as the vapor distribution component, while in some embodiments, the shape of the faceplate may be different from the shape of the vapor distribution component. In some embodiments, the faceplate is configured to attach to the vapor distribution component and to fluidly connect with the vapor distribution component, such that a vapor reactant may pass from the vapor distribution component into the faceplate through a suitable connection. In such embodiments, different faceplates may be utilized to change the nozzle distribution pattern(s) of the vapor distribution component.

In some embodiments, a vapor distribution component includes a plurality of valves that are configured to control the flow of a vapor reactant or a gas. Valves in accordance with embodiments of the invention are configured to be electronically controlled by a suitable controller, such as a programmable logic controller (PLC) that can control the activity of the valves on a suitable time scale. In some embodiments, the valves can be controlled on a time scale of ten milliseconds or less. For example, in some embodiments, a vapor distribution component comprises a plurality of valves that are controlled by a PLC and are configured to carry out a specified deposition sequence by opening and closing in accordance with instructions from the PLC.

Vapor distribution components in accordance with embodiments of the invention are positioned to form a top wall, or ceiling, of a pre-reaction space, as described further herein. In some embodiments, a vapor distribution component is opposed to a substrate support component, i.e., is positioned above the substrate support component such that the nozzles of the vapor distribution component are directed towards the substrate support component.

In some embodiments, a system comprises a vapor feed component that includes a plurality of vapor input lines. Each vapor input line in the vapor feed component is fluidly connected to the vapor distribution component by a connection that comprises a valve. In some embodiments, each vapor input line includes a fluid connection to a purge gas line, wherein the connection comprises a valve. In some embodiments, each vapor input line includes a fluid connection to a carrier gas line, wherein the connection comprises a valve. Each vapor input line comprises a vaporizer that is configured to vaporize a liquid input from a liquid handling system, as described further below. As described above, valves in accordance with embodiments of the vapor feed component are configured to be controlled by a PLC and are responsive to commands from the PLC.

In some embodiments, each of the vapor input lines in the vapor feed component is fluidly connected to each of the other vapor input lines in the vapor feed component by a connection line that comprises a valve. As such, any one or more of the vapor input lines can be combined with any other vapor input line to combine two or more vapor inputs before the vapor inputs reach the vapor distribution component. In some embodiments, a connection line between the vapor feed component and the vapor distribution component includes a heating component that is configured to heat the vapor reactant to a temperature that is high enough to maintain the vapor reactant in the vapor phase, while low enough not to cause unwanted reactions or decomposition. In some embodiments, a heating component is configured to heat a vapor reactant to a temperature ranging from 50 to 300° C., such as 100, 150, 200 or 250° C.

As described above, aspects of the invention include a containment component configured to contain one or more vapor reactants in a pre-reaction space above a substrate. In some embodiments, the containment component is attached to the vapor distribution component and forms an enclosure around a substrate support component, as described further below. In some embodiments, the containment component includes an inner wall that defines an outer dimension of the pre-reaction space, and also includes an outer wall. The distance between the inner wall and the outer wall of the containment component defines the thickness of the containment component.

In some embodiments, the thickness of the containment component varies in the vertical direction. For example, in some embodiments, the inner wall of the containment component is sloped or angled, such that the thickness of the of the containment component changes in the vertical direction. In some embodiments, the thickness of the containment component increases in the vertical direction, while in some embodiments, the thickness of the containment component decreases in the vertical direction. In some embodiments, the thickness of the containment component remains constant in the vertical direction, e.g., the thickness does not change in the vertical direction. Any changes in thickness of the containment component impact the dimensions of the pre-reaction space. For example, when the thickness of the containment component increases in the vertical direction, the dimensions of the pre-reaction space decrease in the vertical direction. When the thickness of the containment component decreases in the vertical direction, the dimensions of the pre-reaction space increase in the vertical direction. In certain embodiments, the containment component comprises a structure that is removably coupled to the inner wall of the containment component and/or the ceiling of the pre-reaction space and is configured to modulate the thickness of the containment component. For example, in some embodiments, the containment component includes an annular ring structure that is removably attached to an upper portion of the inner wall and ceiling of the containment component and which increases the thickness of the containment component in the vertical direction.

In some embodiments, the volume of a pre-reaction space or process zone formed by the inner wall of the containment component, the vapor distribution component, and the substrate support component ranges from 80 to 165 cubic inches, such as 100 to 150 cubic inches.

In some embodiments, the inner wall of the containment component is positioned at a distance away from the outer edge of a substrate support component, forming a gap. In some embodiments, the gap ranges in size from 0.1 to 5 mm, such as 2 to 3 mm. When the substrate support component is moved in the vertical direction, the size of the gap may increase, decrease or remain constant depending of the geometry of the containment component (i.e., depending on the thickness of the containment component, and how the thickness of the containment component changes in the vertical direction).

In some embodiments, the containment component comprises a plurality of gas injection orifices that are disposed on the inner wall of the containment component and are configured to inject a purge gas into the gap, or space between the inner wall of the containment component and the outer edge of the substrate support component. In some embodiments, the gas injection orifices range in diameter from 0.1 to 3 mm, such as 0.5, 1, 1.5, 2 or 2.5 mm. In some embodiments, the gas injection orifices are configured to inject a purge gas at a flow rate ranging from 100 to 20,000 sccm, such as 500, 1,000, 2,000, 3,000, 4,000, 5,000, 6,000, 7,000, 8,000, 9,000, 10,000, 11,000, 12,000, 13,000, 14,000, 15,000, 16,000, 17,000, 18,000 or 19,000 sccm.

In some embodiments, the gas injection orifices are configured to be adjustable, such that the delivery angle at which a purge gas is injected into the gap can be adjusted, and can range from 5 to 85 degrees, such as 30 to 60 degrees, such as 45 degrees, with respect to the plane of the substrate support component. In some embodiments, the delivery angle of a gas injection orifice is fixed (i.e., cannot be adjusted).

In some embodiments, the number of gas injection orifices that are positioned on the inner wall of the containment component ranges from 6 to 60, such as 10 to 20. In some embodiments, the gas injection orifices are evenly spaced along the inner wall of the containment component, while in some embodiments, at least some of the gas injection orifices may be unevenly spaced, or grouped together.

In some embodiments, the containment component may contain a heating element configured to modulate the temperature of the containment component. In some embodiments, the heating element is configured to modulate the temperature of the containment component to a temperature ranging from 50 to 400° C., such as 100, 150, 200, 250, 300, or 350° C.

As described above, aspects of the invention include a substrate support component configured to support a substrate within the reaction chamber. In some embodiments, the substrate support component comprises a flat portion configured to support a substrate, as well as a support post that is configured to move the substrate support component in the vertical direction as well as to rotate the substrate support component about a central, vertical axis. In some embodiments, the substrate support component includes an electrostatic chuck, mechanical chuck and/or other substrate holding apparatus. For certain operations in which the substrate is to be heated, the substrate support component may include a heater, such as a heating plate, that is configured to heat the substrate to a temperature ranging from 50 to 700° C., such as 100, 200, 300, 400, 500, or 600° C.

In some embodiments, the subject systems also include an outer containment component that surrounds the containment component and the substrate support component to form a closed system around the reaction chamber. In some embodiments, the outer containment component includes a vacuum outlet that is configured to connect to a vacuum pump.

In certain embodiments, the methods may be implemented in a chamber equipped for atomic layer deposition (ALD) or chemical vapor deposition (CVD) reactions. In some embodiments, the various components of the systems as described herein are made from suitable materials, including but not limited to aluminum, aluminum oxide, and/or any other suitable material or combinations thereof. In some embodiments, a reaction chamber may include at least one plasma source, such as an RF plasma source. Any suitable plasma source or sources may be used in conjunction with the subject systems and methods.

In some embodiments, a system may include auxiliary components that are well known in the art, including but not limited to carrier gas components, purge gas components, liquid handling components, including liquid handling components that include one or more push gases and associated components and/or vaporizers and associated components, as well as vacuum pumps and associated components.

Additional components of the subject systems include, but are not limited to, controllers (e.g., mass flow controllers (MFCs), pressure injectors/pressure control components, valves and valve controllers, processors, computer-readable media comprising instructions for executing one or more methods as described herein, as well as user interfaces, such as, e.g., a graphical user interface (GUI) configured to receive an input from a user and/or display data or other information to a user.

In some embodiments, aspects of the invention include a controller, processor and computer readable medium that are configured or adapted to control or operate one or more components of the subject systems. In some embodiments, a system includes a controller that is in communication with one or more components of the systems, as described herein, and is configured to control aspects of the systems and/or execute one or more operations or functions of the subject systems. In some embodiments, a system includes a processor and a computer-readable medium, which may include memory media and/or storage media. Applications and/or operating systems embodied as computer-readable instructions on computer-readable memory can be executed by the processor to provide some or all of the functionalities described herein.

In some embodiments, a system includes a user interface, such as a graphical user interface (GUI), that is adapted or configured to receive input from a user, and to execute one or more of the methods as described herein. In some embodiments, a GUI is configured to display data or information to a user.

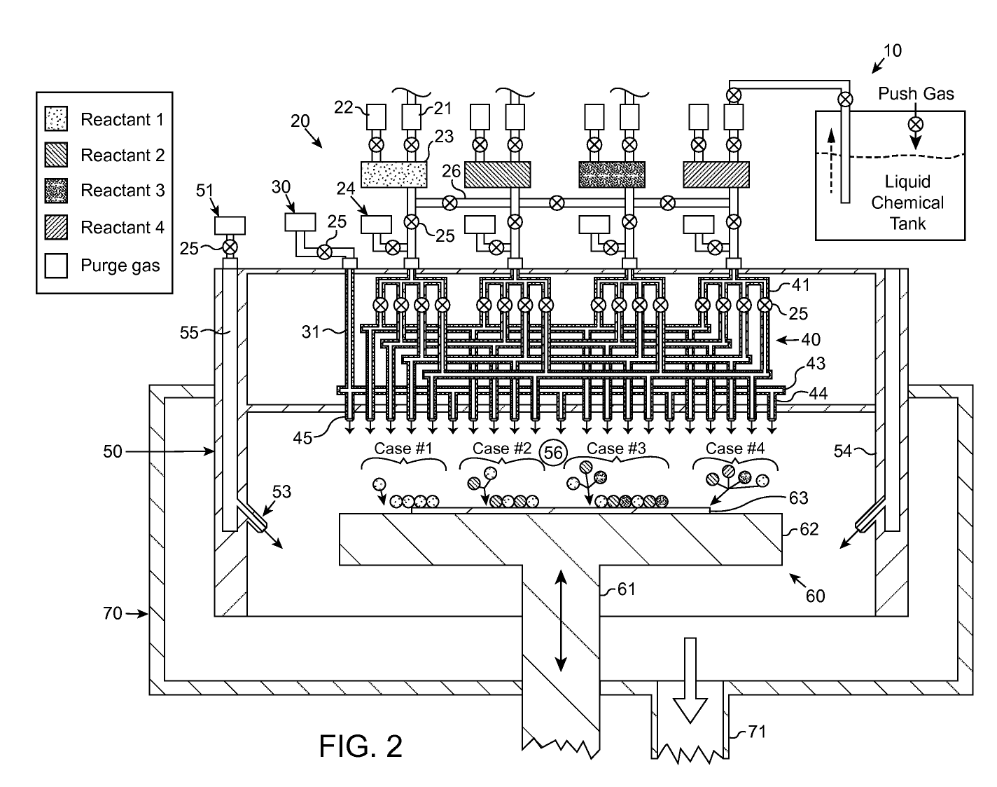

Referring now to FIG. 2, an embodiment of the subject systems is depicted. Liquid handling component 10 delivers liquid reactant precursors to the vapor feed system 20. The depicted liquid handling component 10 includes a liquid chemical tank, or reservoir as well as a push gas component configured to deliver a liquid to the vapor feed component 20. The vapor feed component 20 includes liquid flow controller 21 and carrier gas component 22. Also included in the vapor feed component 20 is a vaporizer 23 that vaporizes a liquid precursor to form a vapor reactant. The vapor feed component 20 also includes a purge gas component 24 as well as several valves 25 that connect various portions of the system. Connection line 26 connects each of the vapor reactant inputs so that one or more vapor reactants can be combined before entering the vapor distribution system 40.

The depicted system further includes a reactant gas input component 30 that is configured to deliver a reactant gas via a connection line 31 to the pre-reaction space 56. The reactant gas component comprises a valve 25 that controls the flow of the reactant gas into the pre-reaction space 56.

The depicted system further includes a vapor distribution component 40 that includes a plurality of connection lines 41 that connect each vapor reactant input to each of the chambers 43 within the vapor distribution system 40. Each connection line 41 includes a valve 25. Each chamber 43 includes a plurality of connection lines 44 that connect the chamber with the pre-reaction space 56. A plurality of nozzles 45 are present on the surface of the vapor distribution component.

The depicted system further includes a containment component 50 that defines the pre-reaction space 56. The containment component 50 includes a purge gas component 51 that includes a valve 25. The purge gas component includes purge gas distribution line 55 that delivers a purge gas to the gas injection orifices 53 that are located on the inner wall 54 of the containment component 50.

The depicted system further includes a substrate support component 60 that includes a support post 61 and a flat portion 62 that is configured to support a substrate 63. The depicted embodiment also includes an outer containment component 70 that includes a vacuum outlet 71 that is configured to connect with a vacuum pump.

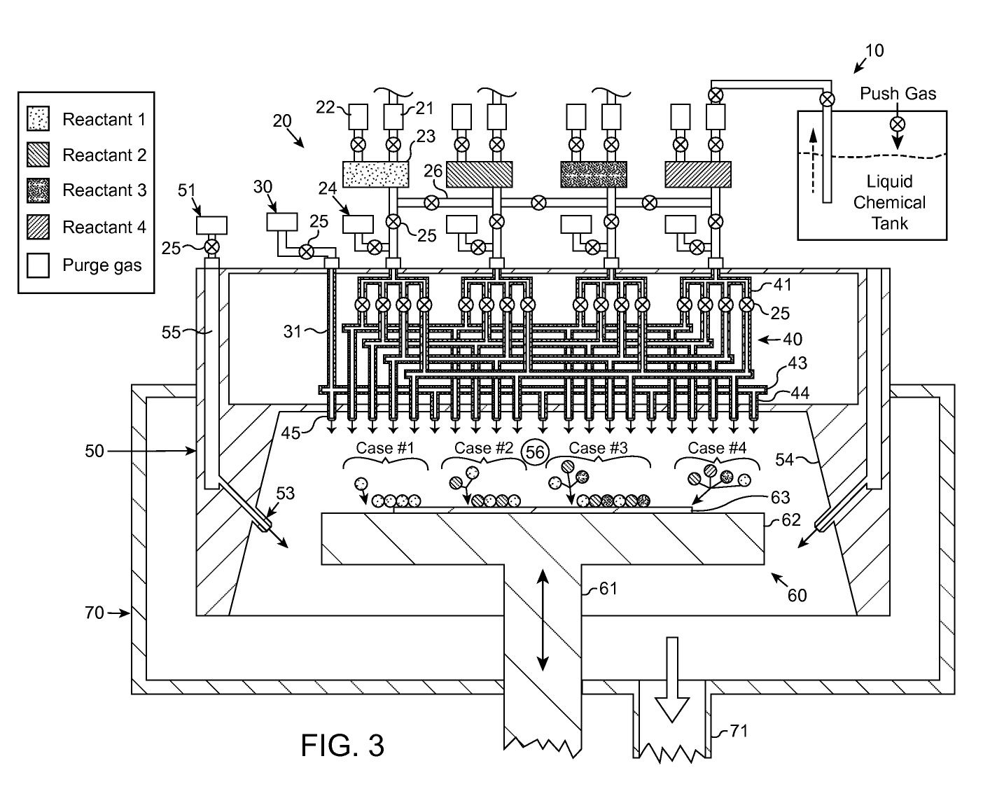

Referring now to FIG. 3, an embodiment of the subject systems is depicted wherein the containment component 50 has an inner wall 54 that angles inward in the vertical direction. As such, the outer dimensions of the pre-reaction space 56 above the substrate 63 are reduced when the substrate support component 60 is moved toward the vapor distribution component 40. In addition, the dimension of the gap or space between the outer edge of the flat portion 62 of the substrate support component 60 and the inner wall 54 of the containment component 50 decreases as the substrate support component 60 is raised toward the vapor distribution component 40.

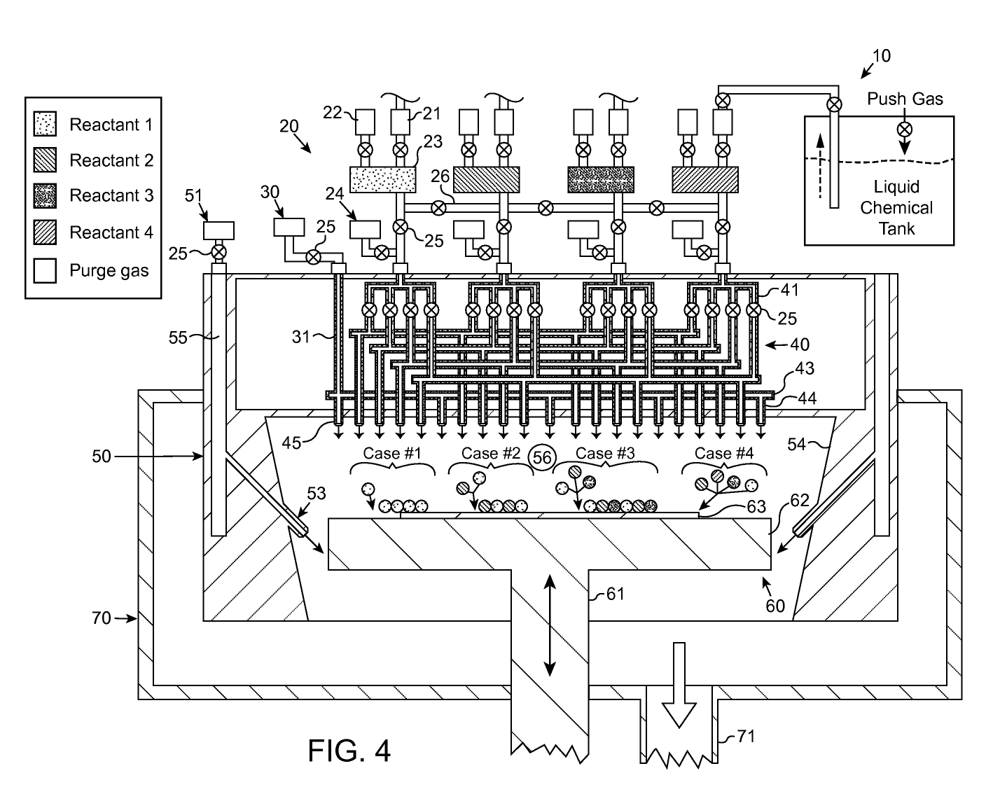

Referring now to FIG. 4, an embodiment of the subject systems is depicted wherein the containment component 50 has an inner wall 54 that angles outward in the vertical direction. As such, the outer dimensions of the pre-reaction space 56 above the substrate 63 are increased when the substrate support component 60 is moved toward the vapor distribution component 40. In addition, the dimension of the gap or space between the outer edge of the flat portion 62 of the substrate support component 60 and the inner wall 54 of the containment component 50 increases as the substrate support component 60 is raised toward the vapor distribution component 40.

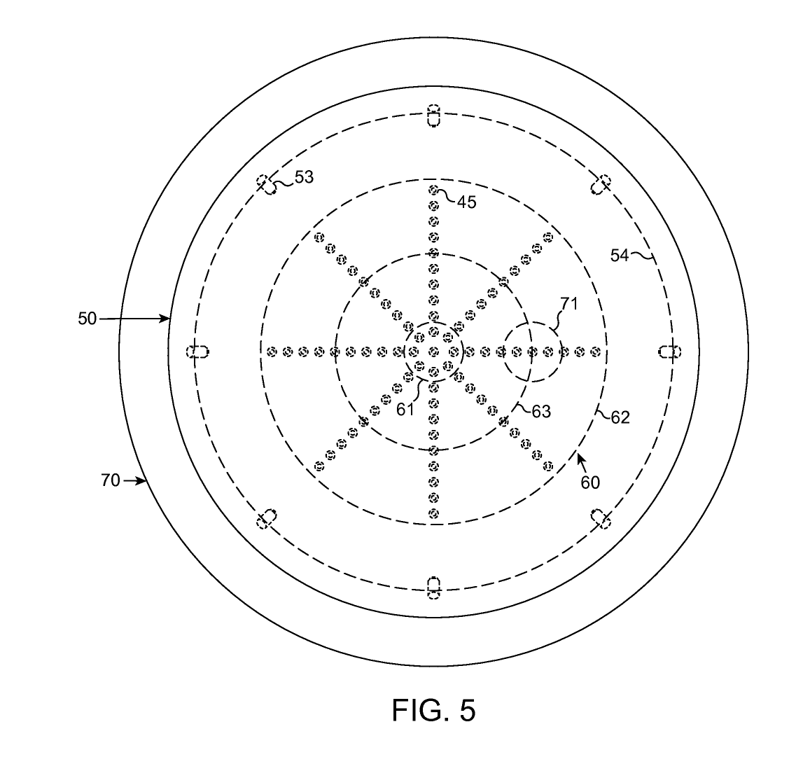

Referring now to FIG. 5, an overhead view of one embodiment of the subject systems is provided. In this embodiment, both the containment component 50 and the outer containment component 70 are circular in shape when viewed from above. The substrate support component 60 includes a flat portion 62 that is also circular in shape when viewed from above. The substrate 63 is also circular in shape when viewed from above. In the depicted embodiment, the nozzles 45 are arranged in a radial distribution pattern above the substrate 63.

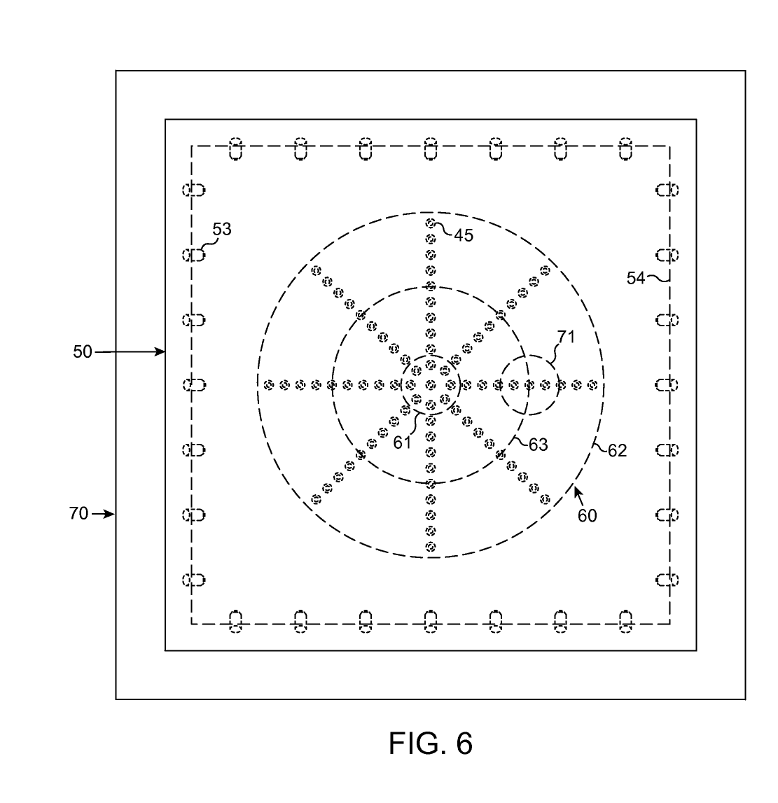

Referring now to FIG. 6, an overhead view of one embodiment of the subject systems is provided. In this embodiment, both the containment component 50 and the outer containment component 70 are square in shape when viewed from above. The substrate support component 60 includes a flat portion 62 that is circular in shape when viewed from above. The substrate 63 is also circular in shape when viewed from above. In the depicted embodiment, the nozzles 45 are arranged in a radial distribution pattern above the substrate 63.

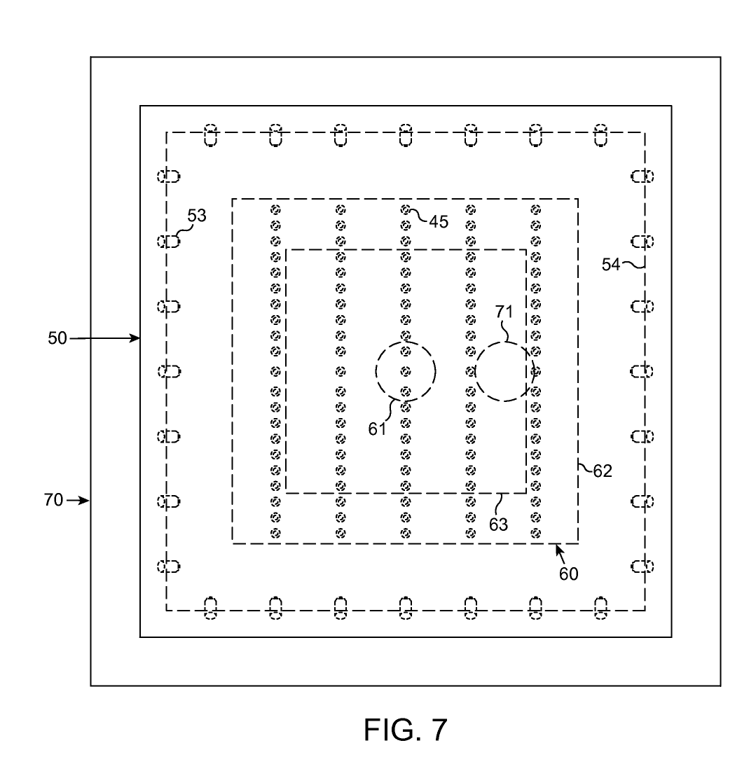

Referring now to FIG. 7, an overhead view of one embodiment of the subject systems is provided. In this embodiment, both the containment component 50 and the outer containment component 70 are square in shape when viewed from above. The substrate support component 60 includes a flat portion 62 that is also square in shape when viewed from above. The substrate 63 is also square in shape when viewed from above. In the depicted embodiment, the nozzles 45 are arranged in evenly spaced rows above the substrate 63.

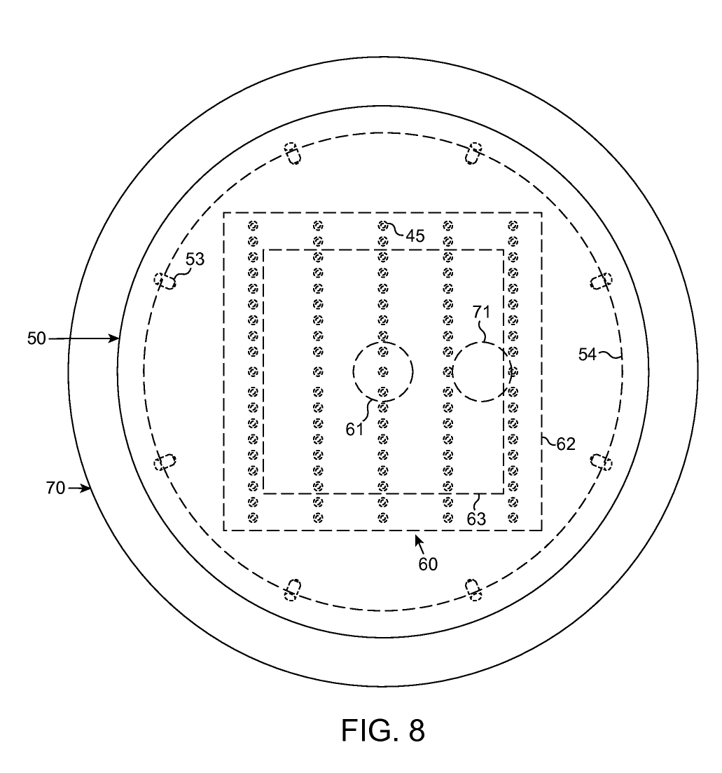

Referring now to FIG. 8, an overhead view of one embodiment of the subject systems is provided. In this embodiment, both the containment component 50 and the outer containment component 70 are circular in shape when viewed from above. The substrate support component 60 includes a flat portion 62 that is square in shape when viewed from above. The substrate 63 is also square in shape when viewed from above. In the depicted embodiment, the nozzles 45 are arranged in evenly spaced rows above the substrate 63.

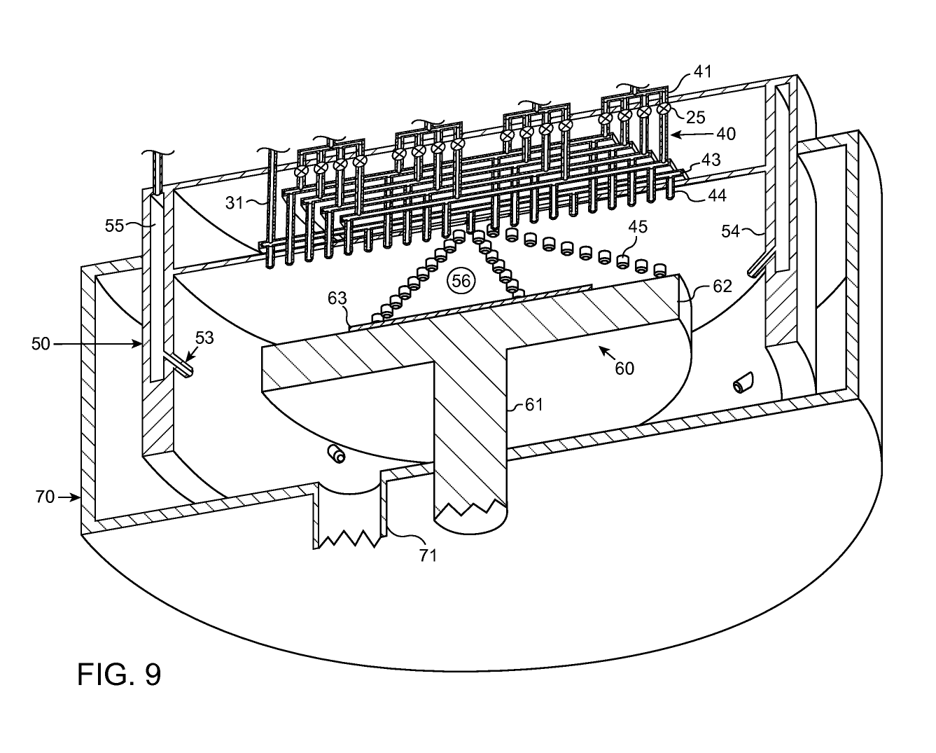

FIG. 9 is a perspective view of an embodiment of the subject systems. The relationship between the vapor distribution component 40, the containment component 50, the substrate support component 60 and the outer containment component 70 can be seen.

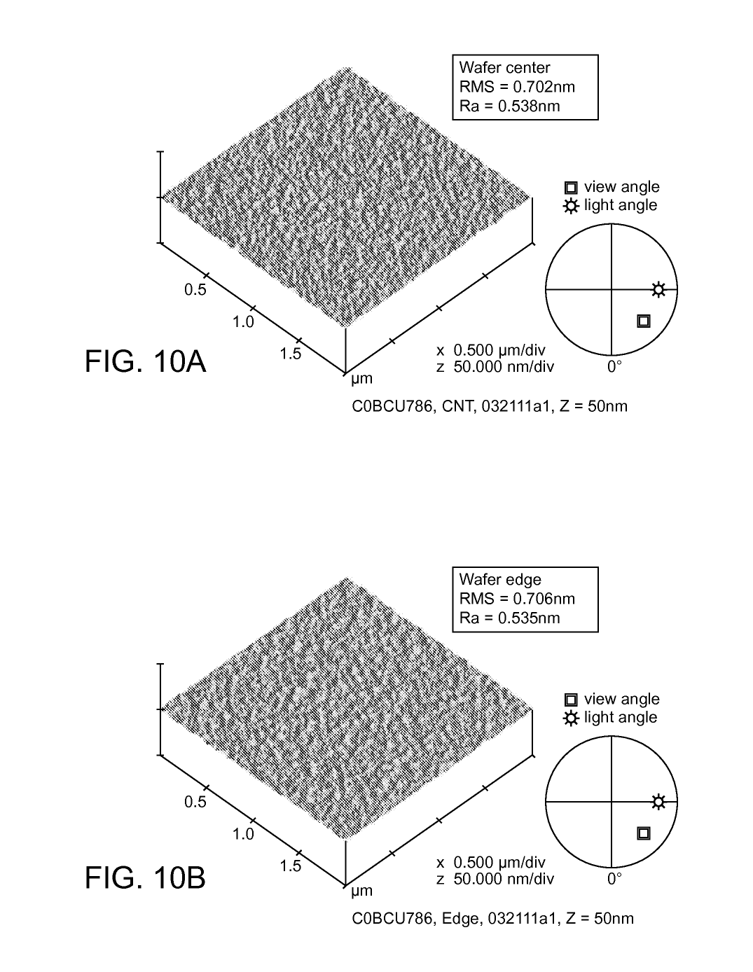

FIG. 10A shows an image of a center portion of a substrate, or wafer, that has been processed using the subject methods and systems. The surface roughness Ra of the resulting thin film at the center of the substrate was 0.538 nm. View angle and light angle are also shown. FIG. 10B shows an image of an edge portion of the same substrate described in FIG. 10A. The surface roughness Ra of the resulting thin film at an edge portion of the substrate was 0.535 nm. View angle and light angle are also shown. The results show that the surface roughness Ra was nearly the same at the center of the substrate and at an edge portion of the substrate, demonstrating that the subject methods and systems can be used to generate a thin film on a substrate having a uniform surface roughness across the entire surface of the substrate.

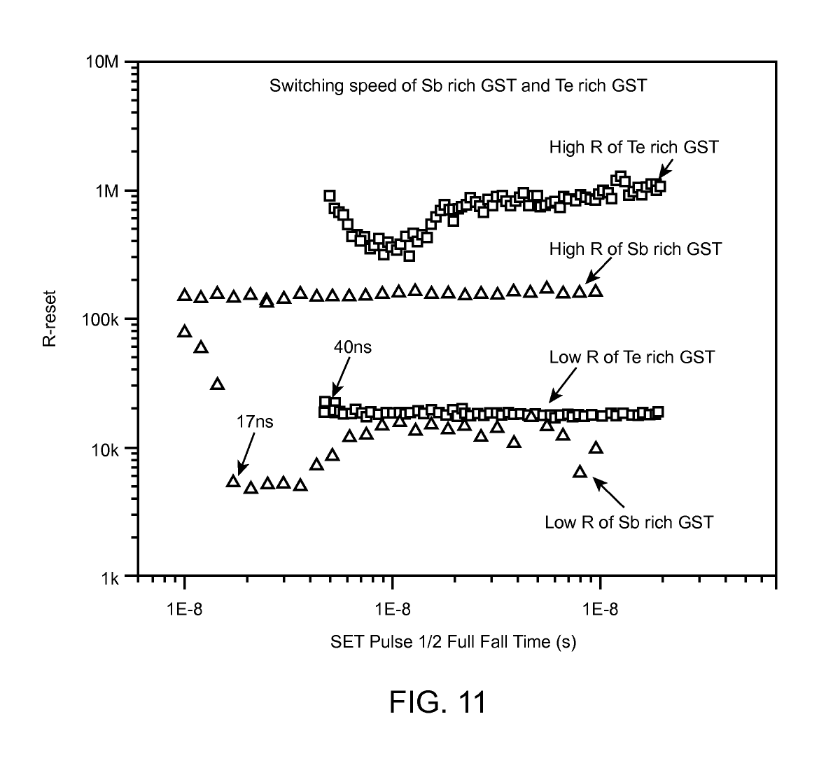

FIG. 11 is a graph showing switching speed of a Te-rich GST film and an Sb-rich GST film created using the subject methods and systems. The results show that the Sb-rich film achieved a very fast switch time of 17 ns, while the Te-rich film also achieved a fast switch time of 40 ns.

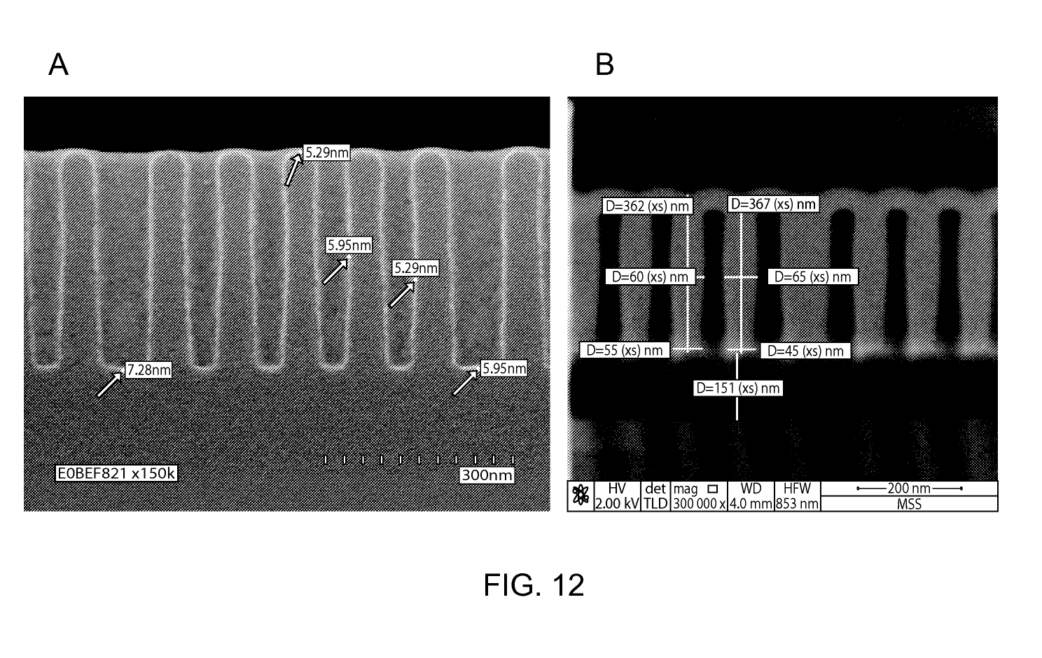

FIG. 12, Panels a and b show images of an Sb-rich GST film created using the subject methods and systems. Panel a shows a substrate having multiple trenches, and shows that the GST film had good conformality over the trenches. Panel b shows a substrate having multiple trenches, and shows that the GST film achieved 100% gap fill.

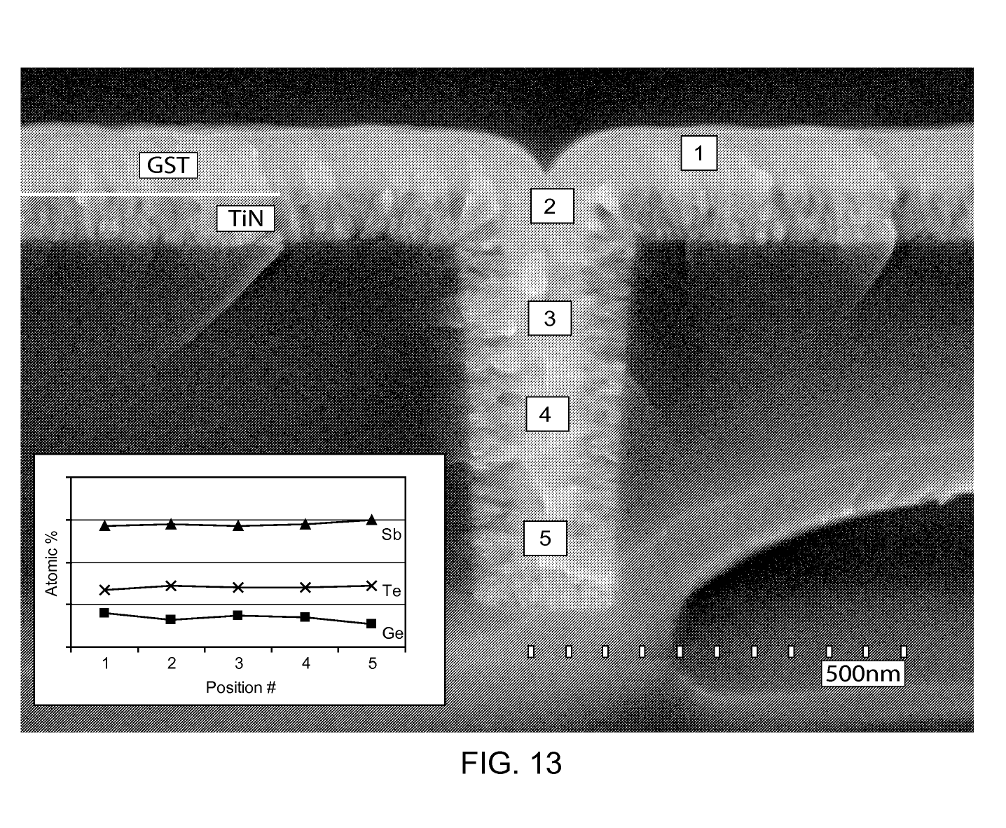

FIG. 13 shows an electron micrograph image of a thin film produced using the subject systems and methods. A GST film that has been formed on a TiN substrate is shown. The substrate contains a trench, or depression, and the GST film has successfully filled the trench. The inset graph demonstrates that the atomic percentage of each component of the GST film is nearly constant at the indicated positions on the surface of the substrate as well as at the various positions within the trench. This result demonstrates that GST films created using the subject methods and systems achieve uniform composition, thickness and gapfill capabilities.

### EXAMPLES

As can be appreciated from the disclosure provided above, the present disclosure has a wide variety of applications. Accordingly, the following examples are set forth so as to provide those of ordinary skill in the art with a complete disclosure and description of how to make and use the present invention, and are not intended to limit the scope of what the inventors regard as their invention nor are they intended to represent that the experiments below are all or the only experiments performed. Those of skill in the art will readily recognize a variety of noncritical parameters that could be changed or modified to yield essentially similar results. Thus, the following examples are put forth so as to provide those of ordinary skill in the art with a complete disclosure and description of how to make and use the present invention, and are not intended to limit the scope of what the inventors regard as their invention nor are they intended to represent that the experiments below are all or the only experiments performed. Efforts have been made to ensure accuracy with respect to numbers used (e.g. amounts, dimensions, etc.) but some experimental errors and deviations should be accounted for.

### Example 1

### SbTe Specific Co-Injection Using Vaporizer with Millisecond Speed Control to Form Different Types of SbTe Film

Sb and Te liquid precursors in the form of Sb(NMe)₃ and Te(tBu), respectively, are each delivered to a separate vaporizer and are vaporized to form Sb- and Te-containing vapor reactants. Fast speed control systems are used to release 0.1 to 1 grams within 20 to 100 milliseconds for each liquid precursor to form the vapor reactants. A carrier gas is used to carry the Sb and Te vapor reactants into a reaction chamber under vacuum, where the Sb and Te reactants are combined with NH₃ as a co-reactant gas. NH₃ is constantly delivered into the reaction chamber to react with the Sb and Te vapor reactants, resulting in the formation of an SbTe film. The vapor reactants are introduced into the reaction chamber as injection pulses, reaching a target partial pressure within the reaction chamber in less than 1 second. One or more vapor reactants can be removed from the reaction chamber by injecting a purge gas through the gas injection orifices located on the inner wall of the containment component, as needed.

The SbTe composition of the film (i.e., the atomic percentage of Sb and Te within the film) is controlled by the number of pulses, the opening time of each injector, and/or the push pressure from the liquid source tank of each precursor during a fixed process time. In a first case, matched injection pulses of Sb and Te are co-injected into the reaction chamber, resulting in an equal composition of Sb and Te in the film. In a second case, matched injection pulses of Sb and Te are first co-injected into the reaction chamber, followed by two discrete injection pulses of Te. In a third case, matched injection pulses of Sb and Te are first co-injected into the reaction chamber, followed by two discrete injection pulses of Sb. In a fourth case, alternating injection pulses of Sb and Te are injected into the reaction chamber, wherein the first injection pulse is Sb, the second injection pulse is Te, the third injection pulse is Sb, and the fourth injection pulse is Te. In a fifth case, matched injection pulses of Sb and Te are staggered with injection pulses of Te, wherein the first injection is a matched injection pulse of Sb and Te, the second injection pulse is Te, the third injection pulse is a matched injection pulse of Sb and Te, the fourth injection pulse is Te, and the fifth injection pulse is a matched injection pulse of Sb and Te.

The Sb and Te composition of the films produced from the five cases described above show that the process sequences can be used to tightly control the relative amount of each material in the thin film. In addition, the properties of the thin film, including conformality, gapfill, thickness and surface roughness, are uniform over the entire surface of the substrate, including central portions of the substrate and edge portions of the substrate.

### Example 2

### GST Specific Co-Injection Using Vaporizer with Millisecond Speed Control to Form GST Film

Sb, Te and Ge liquid precursors are each delivered to a separate vaporizer and are vaporized to form Sb, Te and Ge vapor reactants. Fast speed control systems are used to release 0.1 to 1 grams within 20 to 100 milliseconds for each liquid precursor to form the vapor reactants. A carrier gas is used to carry the Sb, Te and Ge vapor reactants into a reaction chamber under vacuum, where the Sb, Te and Ge reactants are combined with NH₃ as a co-reactant gas. The vapor reactants are introduced into the reaction chamber as injection pulses, reaching a target partial pressure within the reaction chamber in less than 1 second. One or more vapor or gas reactants can be removed from the reaction chamber by injecting a purge gas through the gas injection orifices located on the inner wall of the containment component.

NH₃ is constantly delivered into the reaction chamber to react with the Sb, Te and Ge vapor reactants, resulting in the formation of a GST film. The composition of the film (i.e., the atomic percentage of Ge, Sb and Te within the film) is controlled by the number of pulses, the opening time of each injector, and/or the push pressure from the liquid source tank of each precursor during a fixed process time. In a first case, matched injection pulses of Ge, Sb and Te are co-injected into the reaction chamber, resulting in an equal composition of Ge, Sb and Te in the film. In a second case, matched injection pulses of Sb and Te are first co-injected into the reaction chamber, followed by two discrete injection pulses of Ge. In a third case, alternating injection pulses of Ge, Sb and Te are injected into the reaction chamber, wherein the first injection pulse is Ge, the second injection pulse is Sb, and the third injection pulse is Te. In a fourth case, matched co-injection pulses of Sb and Te are staggered with injection pulses of Ge, wherein the first injection is a matched injection pulse of Sb and Te, the second injection pulse is Ge, the third injection pulse is a matched injection pulse of Sb and Te, the fourth injection pulse is Ge, and the fifth injection pulse is a matched injection pulse of Sb and Te.

The Ge, Sb and Te composition of the films produced from the cases described above shows that the process sequences can be used to tightly control the relative amount of each material in the thin film that forms on the substrate. In addition, the properties of the thin film, including conformality, gapfill, thickness and surface roughness, are uniform over the entire surface of the substrate, including central portions of the substrate and edge portions of the substrate.

### Example 3

### Method of Fabricating High Quality GST Film

An SbTe thin film having a thickness ranging from 5 to 10 Angstroms is first deposited on a substrate using an SbTe co-injection technique described in Example 1, above. Next, a thorough Ar purge of the reaction chamber is used to remove any excess reactants from the chamber. Next, a Ge-containing liquid precursor is delivered to a vaporizer to form a Ge vapor reactant. Ge is introduced into the reaction chamber at a process temperature ranging from 50-700° C. and a process pressure ranging from 2-4 Torr, for a designated period of time. Next, the reaction chamber is purged with Ar to remove the Ge. Next, NH₃ gas is introduced into the reaction chamber under the same reaction conditions for a specified period of time. Next, the reaction chamber is purged with Ar to remove the NH₃. The sequential process of introducing Ge, then purging with Ar, then introducing NH₃, then purging with Ar is repeated until n repetitions have been performed. The result is that Ge is deposited on top of the SbTe thin film, and then diffuses into the SbTe thin film to form a GST thin film. The process of depositing an SbTe film, followed by depositing a Ge layer that diffuses down into the SbTe film can then be repeated, as desired, to form a GST thin film having a uniform thickness over the surface of the substrate. In addition, the properties of the thin film, including conformality, gapfill, thickness and surface roughness, are uniform over the entire surface of the substrate, including central portions of the substrate and edge portions of the substrate.

### Example 4

### Effect of Mixing in Different Portions of the Vapor Distribution Component on GST Film Quality Parameters

A GST thin film is made using the process described above in Example 2. Sb, Te and Ge liquid precursors are each delivered to a separate vaporizer and are vaporized to form Sb, Te and Ge vapor reactants. Fast speed control systems are used to release 0.1 to 1 grams within 20 to 100 milliseconds for each liquid precursor to form the vapor reactants. A carrier gas is used to carry the Sb, Te and Ge vapor reactants into the vapor distribution component.

In a first case, the Sb and Te vapor inputs are combined before reaching the vapor distribution component to form a single SbTe vapor reactant that includes both Sb and Te. The Sb and Te vapor inputs combine while passing through a connection line of the vapor feed component, and pass into the vapor distribution component. The SbTe vapor reactant then passes through the vapor distribution system and is introduced into the pre-reaction space by passing through the nozzles of the vapor distribution component, where it contacts and reacts with the substrate.

In a second case, the Sb and Te vapor inputs are combined within the vapor distribution component by introducing both the Sb and Te vapor inputs into the same chamber within the vapor distribution component. The Sb and Te vapor inputs combine in the chamber to form an SbTe vapor reactant, which then passes into the pre-reaction space by passing through the nozzles of the vapor distribution component, where it contacts and reacts with the substrate.

Following introduction of the SbTe reactant, an injection pulse of Ge is introduced into the chamber and the Ge is maintained for a first period of time. The reaction chamber is then purged with Ar to remove any unreacted Ge. Next, NH₃ gas is introduced into the reaction chamber under the same reaction conditions for a specified period of time. Next, the reaction chamber is purged with Ar to remove the NH₃. The sequential process of introducing Ge, then purging with Ar, then introducing NH₃, then purging with Ar is repeated until n repetitions have been performed. The result is that Ge is deposited on top of the SbTe thin film, and then diffuses into the SbTe thin film to form a GST thin film. The process of depositing an SbTe film, followed by depositing a Ge layer that diffuses down into the SbTe film can then be repeated, as desired to form a GST thin film having a uniform thickness over the surface of the substrate. In addition, the properties of the thin film, including conformality, gapfill, thickness and surface roughness, are uniform over the entire surface of the substrate, including central portions of the substrate and edge portions of the substrate.

### Example 5

### Effect of Gas Injection Rate on GST Film Quality Parameters

A GST thin film is made using the process described above in Example 4. The reaction chamber is configured such that the gap between the inner wall of the containment component and the outer edge of the substrate support component is 2 mm. The substrate support component is maintained in the same position throughout the process (i.e., the vertical height of the substrate support component is not adjusted). The gas injection orifices are adjusted so that the delivery angle of the purge gas is 45° relative to the plane of the substrate. Following reaction of the SbTe vapor reactant with the substrate, the SbTe reactant is removed from the reaction chamber by injecting a purge gas through the gas injection orifices into the gap at a rate ranging from 100 to 20,000 sccm. The Ge reactant is then introduced into the reaction chamber via an injection pulse. By utilizing the gas injection orifices, the SbTe reactant is removed from the reaction chamber and the Ge reactant is established in the reaction chamber at a target partial pressure in less than 1 second.

### Example 6

### Effect of Pre-Reaction Space Volume on GST Film Quality Parameters

A GST thin film is made using the process described above in Example 4. The reaction chamber is configured such that the thickness of the containment component increases in the vertical direction (i.e., the dimensions of the pre-reaction space are reduced in the vertical direction). The gas injection orifices are adjusted so that the delivery angle of the purge gas is 45° relative to the plane of the substrate. Following reaction of the SbTe vapor reactant with the substrate, the substrate support component is raised, thereby reducing the volume of the pre-reaction space. The Ge reactant is then introduced into the reaction chamber via an injection pulse. By changing the vertical height of the substrate support component, the SbTe reactant is removed from the reaction chamber and the Ge reactant is established in the reaction chamber at a target partial pressure in less than 1 second.

### Example 7

### Effect of Gap Dimension on GST Film Quality Parameters

A GST thin film is made using the process described above in Example 4. The reaction chamber is configured such that the gap between the inner wall of the containment component and the outer edge of the substrate support component ranges from 0.1 to 5 mm. The gas injection orifices are adjusted so that the delivery angle of the purge gas is 45° relative to the plane of the substrate. Following reaction of the SbTe vapor reactant with the substrate, the SbTe reactant is removed from the reaction chamber by injecting a purge gas through the gas injection orifices into the gap at a rate of 100 sccm. The Ge reactant is then introduced into the reaction chamber via an injection pulse. By modulating the dimension of the gap between the inner wall of the containment component and the outer edge of the substrate support component, the SbTe reactant is removed from the reaction chamber and the Ge reactant is established in the reaction chamber at a target partial pressure in less than 1 second.

Although the foregoing invention has been described in some detail by way of illustration and example for purposes of clarity of understanding, it is readily apparent to those of ordinary skill in the art in light of the teachings of this invention that certain changes and modifications may be made thereto without departing from the spirit or scope of the appended claims.

Accordingly, the preceding merely illustrates the principles of the invention. It will be appreciated that those skilled in the art will be able to devise various arrangements which, although not explicitly described or shown herein, embody the principles of the invention and are included within its spirit and scope. Furthermore, all examples and conditional language recited herein are principally intended to aid the reader in understanding the principles of the invention and the concepts contributed by the inventors to furthering the art, and are to be construed as being without limitation to such specifically recited examples and conditions. Moreover, all statements herein reciting principles, aspects, and embodiments of the invention as well as specific examples thereof, are intended to encompass both structural and functional equivalents thereof. Additionally, it is intended that such equivalents include both currently known equivalents and equivalents developed in the future, i.e., any elements developed that perform the same function, regardless of structure. The scope of the present invention, therefore, is not intended to be limited to the exemplary embodiments shown and described herein. Rather, the scope and spirit of present invention is embodied by the appended claims.

1.-37. (canceled)

38. A system for depositing a material on a substrate, the system comprising:
a substrate support component having an outer edge;
a vapor distribution component comprising a plurality of chambers, wherein each chamber is fluidly connected to one or more nozzles;
a vapor feed component comprising a plurality of vapor input lines, wherein each of the vapor input lines is in fluid communication with at least one other vapor input line via a connection line comprising a valve, and wherein each of the vapor input lines is in fluid communication with each of the chambers in the vapor distribution component via a connection line comprising a valve;
a containment component having an inner wall and defining a pre-reaction space above the substrate support component, wherein the inner wall is positioned at a distance away from the outer edge of the substrate support component, and wherein the containment component comprises a plurality of gas injection orifices that are adapted to inject a purge gas into a space between the inner wall of the containment component and the outer edge of the substrate support component;
a controller;
a processor; and
a computer-readable medium comprising instructions that, when executed by the processor, cause the controller to:
operate the valves and control a flow rate and a partial pressure of each of a plurality of vapor inputs that are fed into the vapor input lines; and
modulate a pressure level within the pre-reaction space so that a vapor reactant is established at a target partial pressure in the pre-reaction space in less than 1 second.

39. The system according to claim 38, wherein the computer-readable medium comprises instructions that cause the controller to combine two or more vapor inputs before the vapor inputs are introduced into the vapor distribution component to form a vapor reactant.

40. The system according to claim 38, wherein the computer-readable medium comprises instructions that cause the controller to combine two or more vapor inputs within the vapor distribution component to form a vapor reactant.

41. The system according to claim 38, wherein the computer-readable medium comprises instructions that cause the controller to combine two or more vapor inputs within the pre-reaction space to form a vapor reactant.

42. The system according to claim 38, wherein the computer-readable medium comprises instructions that cause the controller to modulate a pressure level within the pre-reaction space so that a first vapor reactant is completely removed from the pre-reaction space before a second vapor reactant is introduced into the pre-reaction space.

43. The system according to claim 38, wherein the computer-readable medium comprises instructions that cause the controller to modulate a pressure level within the pre-reaction space so that a first and a second vapor reactant are both present within the pre-reaction space for a target residence time.

44. The system according to claim 38, wherein the computer-readable medium comprises instructions that cause the controller to modulate a flow rate of a purge gas through the gas injection orifices on the containment component.

45. The system according to claim 38, wherein the distance between the inner wall of the containment component and the outer edge of the substrate support component ranges from 0.1 to 5 mm.

46. The system according to claim 38, wherein the containment component comprises a structure that modulates a dimension of the pre-reaction space in a vertical direction.

47. The system according to claim 38, wherein the substrate support component is configured to move in a vertical direction.

48. The system according to claim 38, wherein the substrate support component is configured to rotate around a vertical axis.

49. The system according to claim 38, wherein the substrate support component comprises a temperature control component that is configured to modulate the temperature of a substrate.

50. The system according to claim 38, wherein the vapor distribution component comprises a temperature control component that is configured to modulate the temperature of a vapor input.

51. The system according to claim 38, wherein the containment components comprises a temperature control component that is configured to modulate the temperature of the pre-reaction space.

52. The system according to claim 38, wherein each of the chambers in the vapor distribution component has a volume ranging from 2.5 to 25 cubic inches.

53. The system according to claim 38, wherein the number of nozzles ranges from 100 to 1200.

54. The system according to claim 38, wherein the nozzles are arranged in a distribution pattern.

55. The system according to claim 38, wherein the vapor distribution component comprises a faceplate upon which the nozzles are mounted.

56. The system according to claim 38, wherein the faceplate is removably coupled to the vapor distribution component.

57. The system according to claim 38, wherein the volume of the pre-reaction space ranges from 80 to 165 cubic inches.

58. The system according to claim 38, further comprising a reactant gas component configured to introduce a reactant gas into the pre-reaction space.

59. The system according to claim 38, further comprising a liquid handling component configured to vaporize a liquid and deliver a vapor input to the vapor feed component.

60. The system according to claim 38, further comprising a carrier gas component configured to move one or more vapors through the system.

61. The system according to claim 38, further comprising a purge gas component configured to purge one or more vapors from at least a portion of the system.

62. The system according to claim 38, further comprising a graphical user interface configured to receive one or more user inputs.

63. The system according to claim 38, further comprising a vacuum pump configured to remove one or more vapors from the pre-reaction space.

64.-68. (canceled)
